(19) United States
(12) Patent Application Publication
(10) Pub. No.: US 2004/0126946 A1
(43) Pub. Date: Jul. 1, 2004

(54) Method for forming transistor of semiconductor device

(76) Inventors: Bong Soo Kim, Seoul (KR); Seung Woo Jin, Icheon-si (KR); Ho Jin Cho, Sungnam-si (KR)

Correspondence Address: HELLER EHRMAN WHITE & MCAULIFFE LLP, 1666 K STREET,NW, SUITE 300, WASHINGTON, DC, 20006, US

(21) Appl. No.: 10/608,816

(22) Filed: Jun. 30, 2003

(30) Foreign Application Priority Data
Dec. 30, 2002 (KR) 2002-87191

(51) Int. Cl. H01L 21/336; H01L 21/8234

(52) U.S. Cl. 438/197; 438/299; 438/301

(57) ABSTRACT

A method for forming a transistor of a semiconductor device wherein a deposition of a buffering oxide film prior to deposition of a nitride film for a gate spacer is performed at a low temperature to prevent out-diffusion of impurities implanted in a source/drain region, thereby providing a semiconductor device with low contact resistance for a bitline and a storage electrode is disclosed. The method for forming a transistor of a semiconductor device comprises the steps of: forming a gate electrode on a semiconductor substrate; ion-implanting impurities into the semiconductor substrate using the gate electrode as a mask to form a source/drain junction region; forming an oxide film on the resulting structure at a temperature below 700° C.; and forming a nitride film spacer on a sidewall of the gate electrode.

### BACKTROUND OF THE IVNENTION

1. Field of the Invention

The present invention relates to a method for forming a transistor of a semiconductor device, and more particularly, to a method for forming a transistor of a semiconductor device wherein a deposition of a buffering oxide film prior to deposition of a nitride film for a gate spacer is performed at a low temperature to prevent out-diffusion of impurities implanted in a source/drain region, thereby providing a semiconductor device with low contact resistances for a bitline and a storage electrode and having improved characteristics and high reliability.

2. Description of the Prior Art

A unit cell of a DRAM device comprises a transistor and a capacitor. Therefore, the characteristic of the transistor is one of the important factors that influence the characteristics of the device.

In a conventional DRAM manufacturing process, a self-aligned contact process wherein a nitride film spacer is formed on a sidewall of a gate electrode is performed to obtain a margin of contact hole etching for forming a cell contact plug.

However, when a nitride film for a nitride film spacer is deposited directly on a semiconductor substrate, the refresh characteristic of the device is degraded due to the stress of the nitride film.

A HTO (high temperature oxide), which is a CVD oxide film and serves as a buffer oxide layer, was introduced to overcome the above-described problem. However, since the formation process of the HTO requires to be performed at a high temperature of 780° C., impurities implanted in a source/drain junction by a blanket ion-implanting process are out-diffused toward the surface of the substrate during the formation process of the HTO.

The out-diffusion phenomenon decreases the dose of impurities in the silicon bulk, i.e. semiconductor substrate to decrease the cell current which affect cell write time delay, and to increase contact resistance of a bitline and a storage electrode, thereby increasing failure of a device.

Although not shown in the drawings, a conventional method for forming a transistor of a semiconductor device is as follows.

A trench-type device isolation film defining an active region is formed on a semiconductor substrate. A stacked structure of a gate oxide film, a conductive layer for a gate electrode and a hard mask layer is deposited on the resulting structure.

Next, the stacked structure is etched via a photolithography using a gate electrode mask to form a gate electrode. Impurities are then ion-implanted into the semiconductor substrate using the gate electrode as a mask.

A HTO is formed on the entire surface of the resulting structure. The HTO is formed at a temperature of more than 780° C. Due to the high temperature, the impurities implanted into the semiconductor substrate are out-diffused.

Next, a nitride film having a predetermined thickness is deposited on the entire surface of the resulting structure, and then anisotropically etched to form a nitride film spacer on a sidewall of the gate electrode.

In the conventional method for forming a transistor of a semiconductor device, the formation process of the HTO for relieving stress between the nitride film and a lower structure requires high process temperature which cause the out-diffusion of impurities implanted in the semiconductor substrate. The out-diffusion increases contact resistance of a bitline and a storage electrode formed in the subsequent process, and degrades the characteristics and reliability of a device.

### SUMMARY OF THE INVENTION

It is an object of the present invention to provide a method for forming a transistor of a semiconductor device wherein a deposition of a buffering oxide film prior to deposition of a nitride film for a gate spacer is performed at a low temperature to prevent out-diffusion of impurities implanted in a source/drain region, thereby providing a semiconductor device with low contact resistances for a bitline and a storage electrode and having improved characteristics and high reliability.

In order to achieve the object of the present invention, there is provided a method for forming a transistor of a semiconductor device, comprising the steps of: forming a gate electrode on a semiconductor substrate; ion-implanting impurities into the semiconductor substrate using the gate electrode as a mask to form a source/drain junction region; forming an oxide film on the resulting structure at a temperature below 700° C.; and forming a nitride film spacer on a sidewall of the gate electrode.

### BRIEF DESCRIPTION OF THE DRAWINGS

FIGS. 1a through 1d are cross-sectional diagrams illustrating a method for forming a transistor of a semiconductor device in accordance with a preferred embodiment of the present invention.

FIG. 2 is a graph illustrating the concentration of impurities according to the depth from the surface of the substrate at a different deposition temperature.

### DETAILED DESCRIPTION OF THE PREFERRED EMBODIMENTS

The present invention will be explained in detail referring to the accompanying drawings.

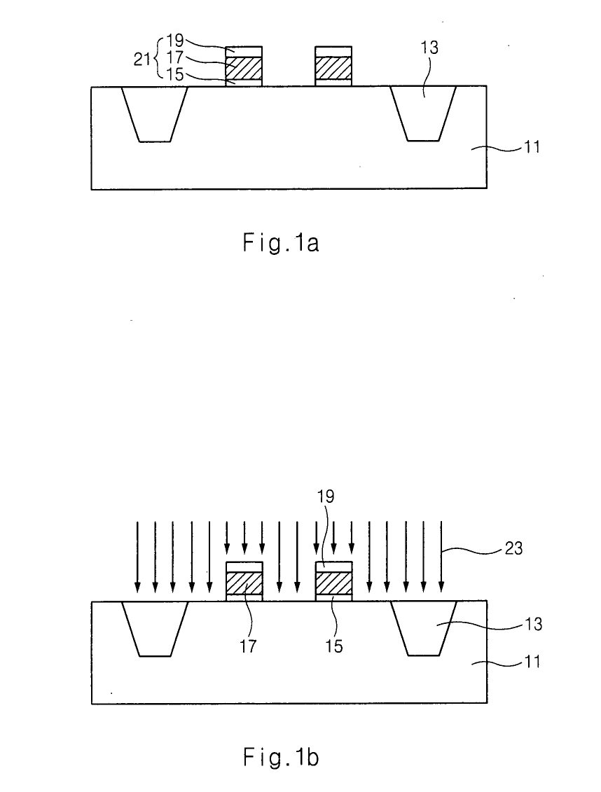

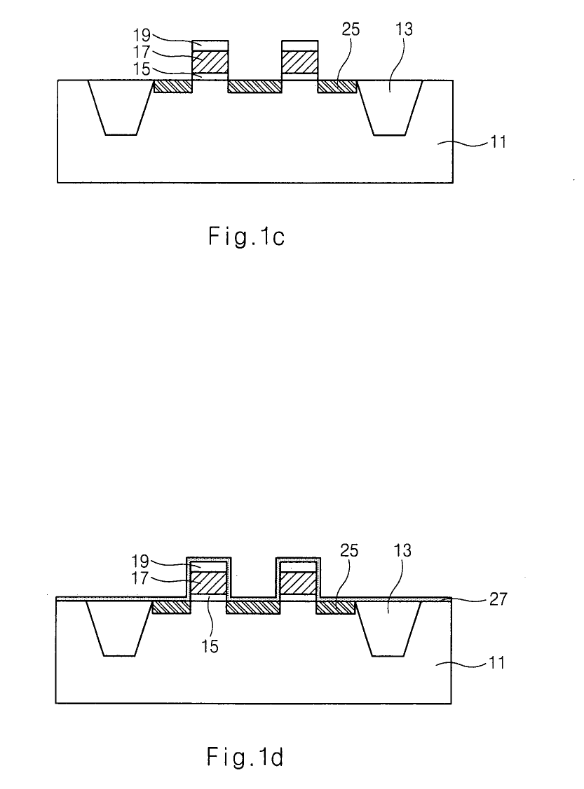

FIGS. 1a through 1d are cross-sectional diagrams illustrating a method for forming a transistor of a semiconductor device in accordance with a preferred embodiment of the present invention.

Referring to FIG. 1a, a trench-type device isolation film 13 defining an active region is formed on a semiconductor substrate 11. Next, a stacked structure of an oxide film (not shown), a conductive layer for a gate electrode (not shown) and a hard mask layer (not shown) is deposited on the entire surface of the resulting structure. Thereafter, the stacked structure is etched via a photolithography using a gate electrode mask to form a gate electrode 21 having a stacked structure of a gate oxide film 15, a conductive layer 17 and a hard mask layer 19. The conductive layer for a gate electrode preferably is a polysilicon film, polycide film or metal film.

Referring to FIGS. 1b and 1c, impurities 23 are ion-implanted into the semiconductor substrate 11 using the gate electrode 21 as a mask to form a source/drain junction region 25. The impurities 23 are preferably ₃₁P or ₇₅As. When ₃₁P is used, an ion-implant energy preferably ranges from 10 to 35 KeV, and a dose ranges from 1.0E12 to 5.0E13 ions/cm². When ₇₅As is used, an ion-implant energy preferably ranges from 15 to 70 KeV, and a dose ranges from 1.0E12 to 5.0E13 ions/cm².

The process of implanting the impurities 23 is preferably performed using a single-type equipment without wafer tilt and rotation, or with wafer tilt of 1° and under bi-rotation or quardruple-rotation configuration. In a case of bi-rotation, ion-implant process is performed twice using ½ of the entire dose. In a case of a quardruple-rotation, ion-implant process is performed four times using ¼ of the entire dose.

Referring to FIG. 1d, an oxide film 27 which is a buffer layer, is formed on the resulting surface.

The oxide film 27 is formed via a CVD or a PVD method at a temperature below 700° C.

When the oxide film 27 is formed via a CVD or a PVD method at a temperature below 600° C., it is preferable that the semiconductor substrate is further subjected to thermal treatment at a temperature ranging from 600 to 700° C. under a nitrogen gas atmosphere. The thermal treatment process is preferably a rapid thermal treatment performed for a time period ranging from 1 to 5 minutes or a thermal treatment performed in a furnace for a time period ranging from 1 minutes to 6 hours.

A nitride film (not shown) is formed on the entire surface of the resulting structure, and then blanket-etched in a subsequent process to form a spacer on a sidewall of the gate electrode.

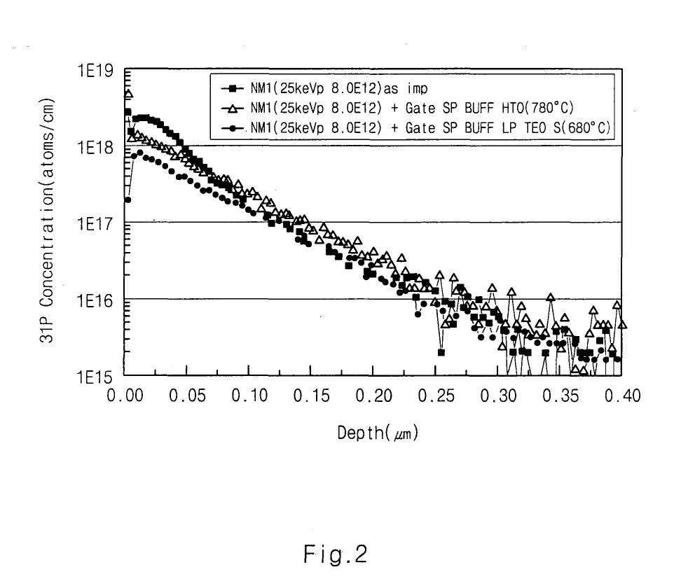

FIG. 2 is a graph illustrating the concentration of impurities according to the depth from the surface of the substrate at a different deposition temperature.

Referring to FIG. 2, dose in the semiconductor substrate larger in case of a LP-TEOS deposited at a temperature of 680° C. than that of a HTO deposited at a temperature of more than 700° C. due to smaller out-diffusion of P (Phosphorous) at a temperature below 600° C.

As discussed earlier, according to a method for forming a transistor of a semiconductor device of the present invention, out-diffusion is minimized by performing the deposition of a buffer oxide film prior to the deposition of a nitride film for a gate spacer at a low temperature, thereby preventing increase of contact resistance of a bitline and a storage electrode and minimizing degradation of characteristics of a device to improve characteristics and reliability of the device.

What is claimed is:

1. A method for forming a transistor of a semiconductor device, comprising the steps of:
forming a gate electrode on a semiconductor substrate;
ion-implanting impurities into the semiconductor substrate using the gate electrode as a mask to form a source/drain junction region by;
forming an oxide film on the resulting structure at a temperature below 700° C.; and
forming a nitride film spacer on a sidewall of the gate electrode.

2. The method according to claim 1, wherein the step of ion-implanting impurities comprises ion-implanting ₃₁P at an energy ranging from 10 to 35 KeV and at a dose ranging from 1.0E12 to 5.0E13 ions/cm².

3. The method according to claim 1, wherein the step of ion-implanting process impurities comprises ion-implanting ₇₅As at an energy ranging from 15 to 70 KeV and at a dose ranging from 1.0E12 to 5.0E13 ions/cm².

4. The method according to claim 1, wherein the ion-implanting process is performed using a single-type equipment without wafer tilt and rotation.

5. The method according to claim 1, wherein the ion-implanting process is performed with a tilt of 1° and in a bi-rotation or a quardruple-rotation configuration using a single-type equipment.

6. The method according to claim 1, wherein the step of forming an oxide film is a CVD or a PVD process.

7. The method according to claim 1, wherein the step of forming an oxide film comprises depositing the oxide film via a CVD or a PVD process performed at a temperature below 600° C., and performing thermal treatment of the semiconductor substrate at a temperature ranging from 600 to 700° C. under a nitrogen gas atmosphere.

8. The method according to claim 7, wherein the thermal treatment is a rapid thermal treatment performed for 1 to 5 minutes or a thermal treatment performed in a furnace for a time period ranging from 1 minutes to 6 hours.

9. The method according to claim 7, wherein the thermal treatment is in a furnace for 1 minutes to 6 hours.
